(19) United States
(12) Patent Application Publication
(10) Pub. No.: US 2012/0293160 A1
(43) Pub. Date: Nov. 22, 2012

(54) FIELD-EFFECT TRANSISTOR INCLUDING MOVABLE GATE ELECTRODE AND SENSOR DEVICE INCLUDING FIELD-EFFECT TRANSISTOR

(75) Inventors: Makoto Koto, Yokohama-shi (JP); Tetsunori Ojima, Kawasaki-shi (JP)

(73) Assignee: CANON KABUSHIKI KAISHA, Tokyo (JP)

(21) Appl. No.: 13/469,875

(22) Filed: May 11, 2012

(30) Foreign Application Priority Data
May 17, 2011 (JP) 2011-110589

(51) Int. Cl. G01R 19/00; H01L 29/78

(52) U.S. Cl. 324/76.11; 257/288; 257/E29.255

(57) ABSTRACT

A field-effect transistor includes a semiconductor layer, at least two active regions disposed in the semiconductor layer, a source electrode in contact with one of the two active regions, a drain electrode in contact with the other active region; an insulating layer which is located between the source electrode and the drain electrode and which is disposed on the semiconductor layer, a gate electrode overlying the insulating layer, an adsorption site which is disposed between the gate electrode and the insulating layer and is used to adsorb a molecule, and a driving unit used to drive the gate electrode.

### BACKGROUND OF THE INVENTION

1. Field of the Invention

One disclosed aspect of the embodiments relates to a field-effect transistor including a movable gate electrode and a sensor device including the field-effect transistor.

2. Description of the Related Art

Various sensors have been proposed or have been in practical use as sensor needs have become diverse. For example, a sensor detecting a change in conductivity due to a redox reaction on a surface of an oxide semiconductor has been in practical use and is used to detect methane, isoprene, a fluorohydrocarbon gas, alcohol, or the like.

Controlled Potential Electrolysis sensors for measuring the flow rate of gas may detect carbon monoxide, hydrogen sulfide, halogens, ozone, nitrogen oxides, hydrogen chloride, and the like. For other detection techniques, field-effect transistor sensors, including semiconductor devices, for detecting the surface potential have been proposed.

The field-effect transistor sensors have advantages such as quick response, the capability of detecting various target molecules by changing recognition sites, and ease in integration and are expected to have broad increased applications and cost reduction potentials.

In a field-effect transistor sensor, a difference in charge or potential is caused between a channel and a gate electrode or a voltage-applied portion and thereby the charge in the channel is varied. The detection principle of the field-effect transistor sensor is that the conductance of the channel varies the change in charge to cause a drain current.

Therefore, the field-effect transistor sensor preferably has a configuration that enables the access of target molecules to a region between the channel and the gate electrode or the voltage-applied portion.

U.S. Patent Application Publication No. 06/544359 (hereinafter referred to as Patent Literature 1) discloses a sensor for detecting a component of a fluid. In the sensor, a channel region and gate electrode of a field-effect transistor are spaced from each other and accessibility is secured by a gap therebetween.

In the sensor, target molecules may freely move in the gap and therefore there are few limitations on target samples. Furthermore, the sensor may be used to measure an alcohol component contained in a vapor without using any electrolytic solution.

The sensor disclosed in Patent Literature 1 has the gap near the gate for the purpose of securing accessibility. The gap causes a reduction in the capacitance of the gate, leading to a reduction in sensitivity.

### SUMMARY OF THE INVENTION

One disclosed aspect of the embodiments provides a field-effect transistor, unlikely to reduce the sensitivity of a field-effect transistor sensor, for detecting molecules in a liquid.

An embodiment provides a field-effect transistor including a semiconductor layer, at least two active regions disposed in the semiconductor layer, a source electrode in contact with one of the two active regions, a drain electrode in contact with the other active region, an insulating layer which is located between the source electrode and the drain electrode and which is disposed on the semiconductor layer, a gate electrode overlying the insulating layer, an adsorption site which is disposed between the gate electrode and the insulating layer and is used to adsorb a molecule, and a driving unit used to drive the gate electrode.

According to the embodiments, a field-effect transistor may be provided. The field-effect transistor has high sensitivity because a gate electrode included in the field-effect transistor is movable and therefore does not prevent molecules from being adsorbed on an adsorption site.

Further features of the disclosure will become apparent from the following description of exemplary embodiments with reference to the attached drawings.

### BRIEF DESCRIPTION OF THE DRAWINGS

FIG. 1 is an illustration showing the configuration of a field-effect transistor according to a first embodiment.

FIGS. 2A and 2B are illustrations schematically showing the configuration of a field-effect transistor device according to the first embodiment.

FIG. 3 is an illustration showing a detection method using a field-effect transistor according to a second embodiment.

FIGS. 4A and 4B are illustrations showing results obtained by simulating changes in properties of a field-effect transistor in the presence or absence of a gap.

FIGS. 5A and 5B are illustrations showing steps of a method of preparing a field-effect transistor device described in Example 1.

FIGS. 6A and 6B are illustrations showing steps of a detection method using a field-effect transistor device described in Example 2.

### DESCRIPTION OF THE EMBODIMENTS

### First Embodiment

A first embodiment provides a field-effect transistor including a semiconductor layer; at least two active regions disposed in the semiconductor layer; a source electrode in contact with one of the two active regions; a drain electrode in contact with the other active region; an insulating layer which is located between the source electrode and drain electrode and which is disposed on the semiconductor layer; a gate electrode overlying the insulating layer; an adsorption site, disposed between the gate electrode and the insulating layer, for adsorbing a molecule; and a driving unit for driving the gate electrode.

In the field-effect transistor, the insulating layer is disposed between the source electrode and the drain electrode and is in contact with the semiconductor layer and the adsorption site is in contact with the insulating layer.

In the field-effect transistor, the gate electrode overlies the adsorption site. The gate electrode is configured to move vertically or horizontally.

When specific molecules in gas are adsorbed on the adsorption site, the gate electrode is spaced from the adsorption site. When the number of the adsorbed molecules is measured, the gate electrode is in contact with the adsorption site.

Since the gate electrode is spaced from the adsorption site during adsorption, the contact area between the adsorption site and gas is large. Therefore, the adsorption site may come into contact with gas without being disturbed by the gate electrode.

Since the gate electrode is in contact with the adsorption site during the measurement of the adsorbed molecules, the number of the adsorbed molecules may be measured without impairing the capacitance thereof. This enables high-sensitivity detection.

Since the contact area between the adsorption site and gas is large and the capacitance is not impaired during measurement, the field-effect transistor has high detection sensitivity.

The adsorption site adsorbs a specific molecule in gas and may include an organic or inorganic membrane.

The field-effect transistor may detect the charge of a target molecule or the charge induced by the contact between the target molecule and the adsorption site.

The field-effect transistor may detect a dipole induced by the adsorption of the target molecule and the change in potential of the dipole of the target molecule. Furthermore, the field-effect transistor may detect the space charge induced by the adsorption of the target molecule, the change in dielectric constant of the adsorption site, and the like.

The adsorption site preferably has selectivity to the target molecule from the viewpoint of application to sensors. The selectivity thereof may be chemical affinity, chemical bonding, chemical interaction, or physical interaction.

A change induced by trapping the target molecule may be a change in charge, a change in potential, or both of such changes.

The adsorption site preferably has a molecule or functional group selectively binding to a specific molecule such as an antibody, a DNA, a protein, a peptide, a receptor, a ligand for the receptor, a clathrate compound, a calixarene, or a synthetic molecule.

The adsorption site may include a thin film prepared by a molecular template technique. This is preferred because the adsorption site selectively adsorbs a specific molecule.

The adsorption site is preferably thin and particularly preferably has a thickness of 10 nm or less.

The adsorption site may be formed so as to have a thickness of 10 nm or less using a synthetic polymer layer fixed on a low-molecular substrate or prepared by a molecular template method.

The adsorption site preferably has a large effective surface area per unit volume from the viewpoint of trapping the target molecule.

The adsorption site may have fine roughness, a porous structure, or the like to achieve an increased surface area. In order to allow the field-effect transistor to detect a signal from the target molecule adsorbed on the adsorption site, the adsorption site may be in contact with the insulating layer or the gate electrode.

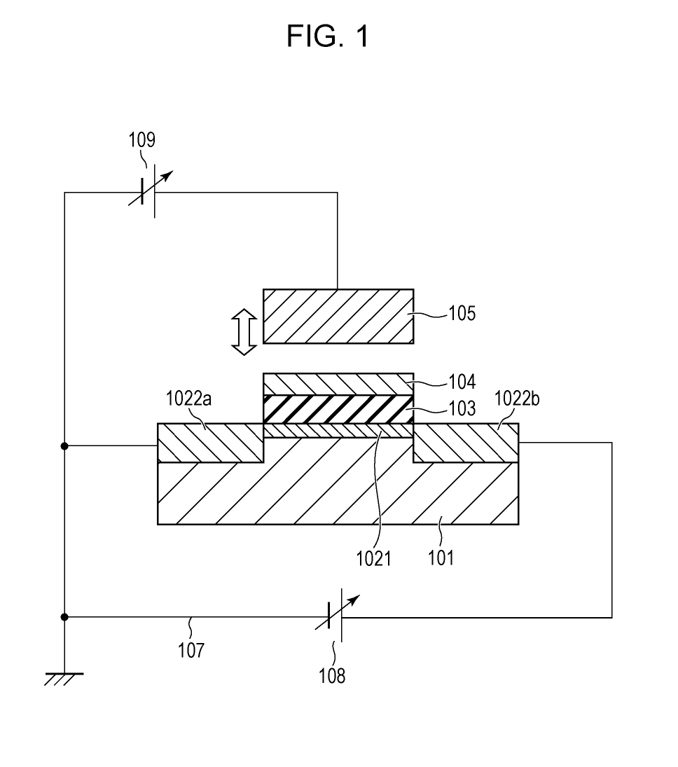

The field-effect transistor is described below with reference to FIG. 1.

A substrate 101 may be made of a material capable of forming the field-effect transistor. Examples of such a material include element semiconductors such as Si, Ge, and C; compound semiconductors such as SiGe, GaAs, InP, AlAs, SiC, and GaN; and oxide semiconductors such as ZnO and In₂O₃.

The substrate 101 may be doped with an impurity. The polarity of the impurity is not limited.

Impurity layers and insulating layers may be formed by known semiconductor processes.

A channel impurity layer 1021 and source/drain source/drain impurity layers 1022a and 1022b may be formed by the ion implantation of an n-type impurity such as P or As or a p-type impurity such as B when the substrate 101 is made of Si.

The type and concentration of an impurity used may be determined in consideration of the type and impurity concentration of the substrate 101 on the basis of transistor characteristic design guidelines such as an enhancement/depletion type and the adjustment of a threshold voltage.

When the substrate 101 is made of, for example, Si, the channel impurity layer 1021 has an impurity concentration of 1×10¹⁷ to 1×10¹⁸ atoms/cm³ and the source/drain impurity layers 1022a and 1022b have an impurity concentration of about 1×10²⁰ atoms/cm³.

When the field-effect transistor has an n-type channel or a p-type channel, the source/drain impurity layers 1022a and 1022b are doped with the n-type impurity or the p-type impurity, respectively.

The channel impurity layer 1021 has an impurity concentration as a total amount of substrate impurity concentration and an additionally added impurity concentration. When the source/drain impurity layers 1022a and 1022b are doped with the n-type impurity, doping the channel impurity layer 1021 with the n-type impurity or the p-type impurity allows the channel impurity layer 1021 to be of a depletion type or an enhancement type, respectively.

In contrast, when the source/drain impurity layers 1022a and 1022b are doped with the p-type impurity, doping the channel impurity layer 1021 with the p-type impurity or the n-type impurity allows the channel impurity layer 1021 to be of a depletion type or an enhancement type, respectively.

When the substrate 101 is made of a material other than Si, the source/drain impurity layers 1022a and 1022b may be doped with the n- or p-type impurity.

For impurity doping, an ion implantation process, an impurity diffusion process, or the like may be used.

When the substrate 101 is made of Si, an insulating layer 103 may be made of SiO₂, SiN, or SiON. The insulating layer 103 is preferably formed by thermal oxidation from the viewpoint of dielectric strength and chemical stability and may be formed by chemical vapor deposition (CVD). The insulating layer 103 may be one having electrical insulation and is preferably one that is chemically stable.

A material for forming a gate electrode 105 is preferably selected depending on the type or impurity concentration of the channel impurity layer 1021, in which a channel is formed.

This is because band bending in the channel impurity layer 1021 is affected by the Fermi level of the channel impurity layer 1021 and the work function of the material for forming the gate electrode 105.

Several processes may be used to form a gap between the gate electrode 105 and the channel impurity layer 1021. For example, after an adsorption site 104 is formed, a sacrificial layer, which is not shown, is formed, the gate electrode 105 is formed on the sacrificial layer, and the sacrificial layer is selectively removed, whereby a device configuration shown in FIG. 1 is obtained.

The gate electrode 105 is preferably moved close to or away from the channel impurity layer 1021 in order to measure the target molecule.

Driving force for moving the gate electrode 105 may be mechanical force, magnetic repulsive force, or attractive force.

A piezoelectric element or the like may be used to generate mechanical force.

In order to use magnetic repulsive or attractive force, the gate electrode 105 may be magnetic or a driving section moving synchronously with the gate electrode 105 may have a magnetic structure. In this case, the movement of the gate electrode 105 may be controlled by applying an appropriate magnetic field to the gate electrode 105 from outside.

The following configuration is possible: a configuration in which the gate electrode 105 is made of a porous material and the adsorption site 104, which is disposed under the gate electrode 105, is in contact with gas. In this configuration, the adsorption of gas on the adsorption site 104 is slightly suppressed and therefore the sensitivity of detection may possibly be impaired. However, the adsorption site 104 is constantly in contact with gas and no driving mechanism is necessary. Therefore, this configuration is suitable for downsizing.

In order to apply voltages between the gate electrode 105 and the two source/drain impurity layers 1022a and 1022b, a voltage source 108 is electrically connected to the source/drain impurity layers 1022a and 1022b through connection lines 107.

Furthermore, a source-gate voltage source 109 is electrically connected to the source/drain impurity layer 1022a and the gate electrode 105 through connection lines 107.

The source/drain impurity layer 1022a is grounded.

The grounding of the source/drain impurity layer 1022a is for exemplification.

The source/drain impurity layers 1022a and 1022b are indistinguishable from each other in principle; hence, if the source/drain impurity layers 1022a and 1022b are replaced with each other, the source/drain impurity layers 1022a and 1022b function similarly.

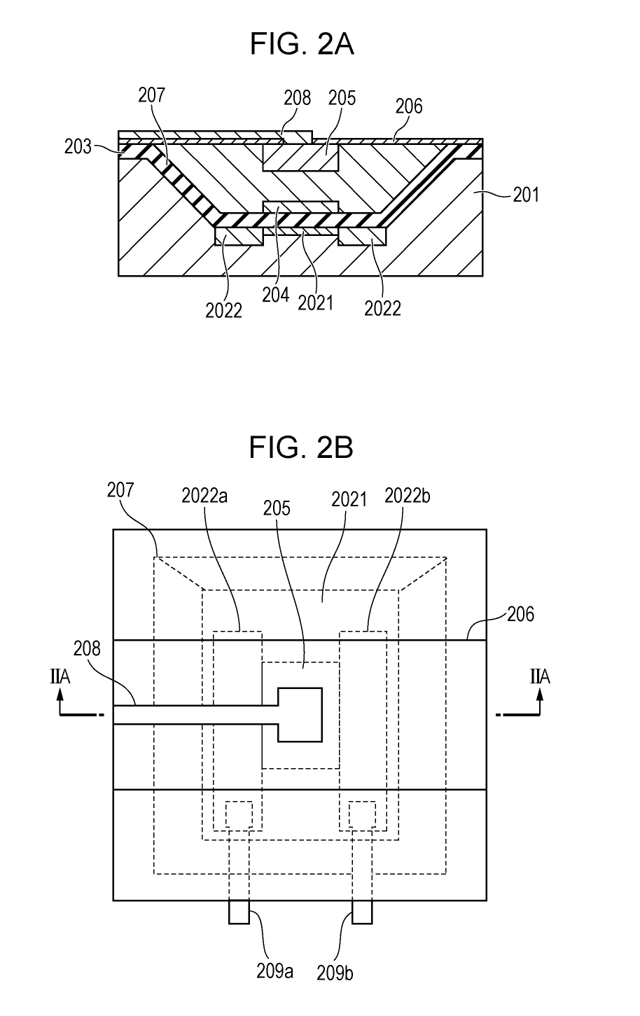

FIGS. 2A and 2B show a device, including the field-effect transistor, for measurement. FIG. 2A is a sectional view of the device taken along the line IIA-IIA of FIG. 2B. FIG. 2B is a plan view of the device. A recessed section 207 is formed by processing a substrate 201.

When the substrate 201 is made of Si, a (100)-oriented surface of the substrate 201 is etched with a KOH solution, whereby etching is stopped at a (111)-oriented surface thereof and the recessed section 207 is formed so as to have a tapered shape.

Impurity layers 2021, 2022a, and 2022b; an insulating layer 203; an electrode 205; and a suspension film 206 are formed using materials and processes similar to those used to form the components shown in FIG. 1. The impurity layers 2022a and 2022b are electrically connected to source/drain lines 209a and 209b, respectively, such that a potential is applied to each of the impurity layers 2022a and 2022b.

The suspension film 206 is preferably made of a flexible material such that the suspension film 206 is detached from the adsorption site in a step of adsorbing the target molecule and is moved close to or attached to the adsorption site in a step of measuring the target molecule.

SiN may be applied for the suspension film 206 because it is standard material to form membrane structure for MEMS device. A resin material or the like may be used to form the suspension film 206 depending on other components.

In order to maintain the reproducibility of the distance between the electrode 205 and the impurity layer 2021, the substrate 201 and the suspension film 206 are preferably configured to be tightly bonded to each other.

Spaces on an upper portion and lower portion of the electrode 205 are preferably not isolated such that the target molecule may readily access the electrode 205 from outside.

Therefore, the suspension film 206 is configured such that the recessed section 207 is partly exposed as shown in FIG. 2B.

A gate line 208 for supplying a potential to the electrode 205 is provided. The gate line 208 may be connected to the electrode 205 in such a manner that a through-hole is formed in the suspension film 206 and the gate line 208 is formed on the suspension film 206 so as to extend through the through-hole as shown in FIG. 2B. The device, which is described in Example 1, is manufactured as described above.

### Second Embodiment

A second embodiment provides a method of detecting a component in a fluid and measuring the concentration of the component using a device including a semiconductor substrate; at least two diffusion layers disposed on the semiconductor substrate; an insulating layer which is located between the diffusion layers and which is disposed on the semiconductor substrate; an electrode which is located such that the electrode and the semiconductor substrate sandwich the insulating layer; and an adsorption site, disposed between the insulating layer and the electrode, for adsorbing a molecule, the electrode being prepared such that the electrode and the semiconductor substrate sandwich a gap. The method includes a step of introducing a target molecule into the gap between the semiconductor substrate and the electrode and holding the target molecule therein for a predetermined time, a step of moving the electrode close to the semiconductor substrate, and a step of applying predetermined transistor-driving voltages to the diffusion layers and the electrode to perform measurement, these steps being performed in that order.

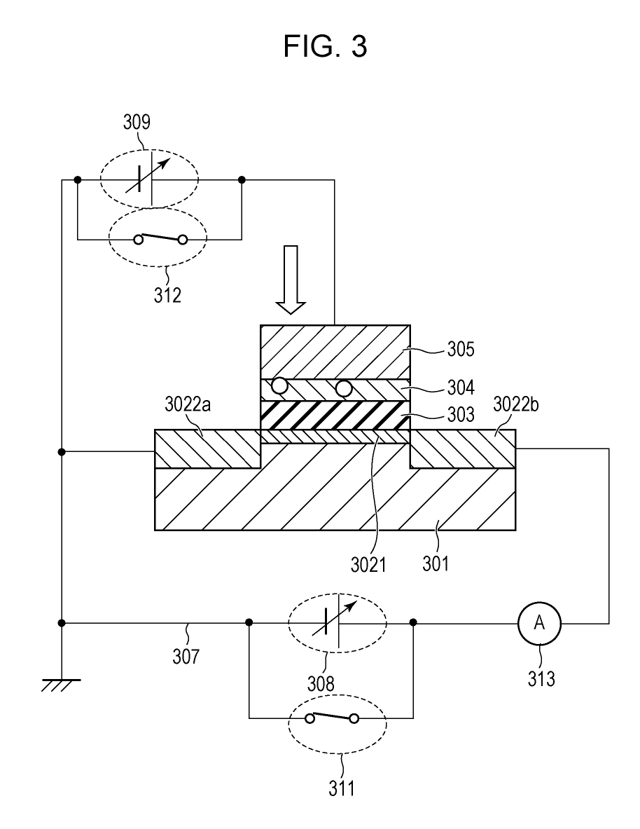

FIG. 3 is a schematic view of a measurement procedure. Switches 311 and 312 are turned on, whereby impurity regions 3022a and 3022b and a gate electrode 305 are held at the same potential. The gate electrode 305, a source, and a drain are at the same potential and therefore no current is generated therebetween.

The switches 311 and 312 are used in this embodiment. When a gate-source power supply 309 and source-drain power supply 308 below are voltage-variable power supplies, voltages may be increased or decreased as required without using any switches.

The gate electrode 305 is detached from a channel impurity layer 3021. The distance between the channel impurity layer 3021 and the gate electrode 305 detached therefrom is within a range determined by the movable range of a piezoelectric element used to move the gate electrode 305 or the distance between a gate and an impurity region described in the Related Art (Patent Literature 1). In particular, the distance between the channel impurity layer 3021 and the gate electrode 305 detached therefrom is preferably 10 nm or more and more preferably 100 nm or more.

In this embodiment, an adsorption site 304 is in contact with an insulating layer 303. When an external space is surrounded by a fluid containing target molecules 310, the target molecules 310 diffuse in the external space to reach the adsorption site 304.

For quantitative detection, the time to keep the gate electrode 305 detached is preferably controlled. This is because the difference between changes is thought to be substantially proportional to the difference between concentrations in the external space in the case of repeating measurement several times under an equal exposure time condition.

In a conventional example, a gap is always present and an adsorption site is exposed; hence, it is difficult to suppress time-series variables. However, in this embodiment, the exposure of the adsorption site 304 may be reduced or suppressed and therefore time-series variables may be suppressed.

The gate electrode 305 is moved close to the channel impurity layer 3021.

Since a gap between the gate electrode 305 and the channel impurity layer 3021 is reduced, the reattachment and/or redistribution of the target molecules 310 and non-target molecules present in a region near the gate electrode 305 in the gap therebetween may be reduced or suppressed.

The switches 311 and 312 are turned off. Appropriate voltages are applied to the gate-source power supply 309 and the source-drain power supply 308. In particular, the voltage applied between the source and a gate is preferably about 0.1 V to 15 V and the voltage applied between the source and the drain is preferably about 0.1 V to 5 V.

Since the switches 311 and 312 are turned off, predetermined voltages are applied between the gate and the source and between the source and the drain; hence, a current flows into the drain. This current is measured with an ammeter 313.

A change proportional to the number of the target molecules 310 adsorbed on the adsorption site 304 is reflected in the change in current of the drain.

The target molecules 310 in the fluid present in the external space may be detected by repeating the above steps.

The target molecules 310 may be desorbed from the adsorption site 304 by maintaining the external space for a long time in such a state that the external space is surrounded by a fluid containing no target molecules 310.

The desorption of the target molecules 310 is preferably facilitated by raising the temperature of a substrate from the viewpoint of the improvement in measurement reproducibility of the field-effect transistor and the repeated use of the field-effect transistor.

When a gap is created, the distance between an electrode and a channel is increased and a low-dielectric constant material is introduced between the electrode and the channel; hence, the capacitance of the gate is significantly reduced, resulting in that the rate of change in current with respect to the voltage is significantly reduced.

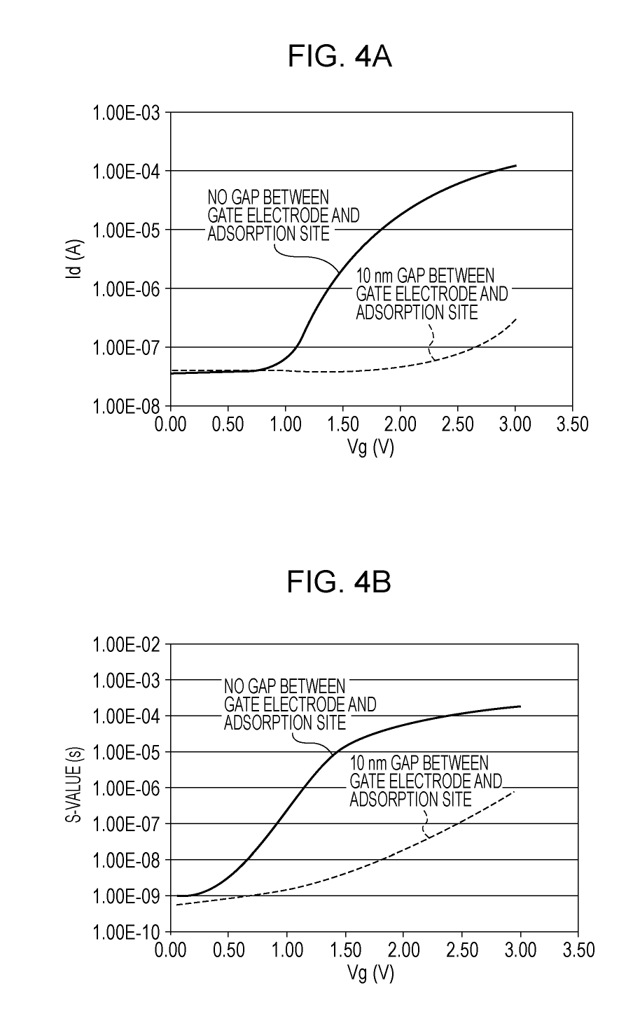

For confirmation, simulations were performed using a system close to the device, which includes the field-effect transistor, whereby changes in properties due to the presence or absence of a gap were measured. The obtained results are shown in FIGS. 4A and 4B. Simulation conditions are as described below.
Simulator: ATLAS (Silvaco International)
Gate width: 1 μm
Gate length: 0.5 μm
Insulating layer: 15 nm
Gap: absent or present (10 nm)

As is clear from FIG. 4A, the drain current is decreased by three orders of magnitude at a gate voltage Vg of about 1.0 to 2.5 V. The voltage dependence of the S-value, which represents the change in current with respect to the voltage, may be confirmed from FIG. 4B, which shows a difference of several orders of magnitude. This confirms that the presence of a gap causes a reduction in sensitivity.

A field-effect transistor according to this embodiment may be used as a sensing system in such a manner that changes in current properties are obtained by applying a voltage thereto.

A sensing system according to this embodiment includes a sensing section including a field-effect transistor.

A voltage-applying unit for applying a voltage may be a known direct- or alternating-current power supply.

A current-measuring unit for measuring current properties may be a commercially available micro-ammeter.

The voltage-applying unit and the current-measuring unit may be combined with or separated from each other and are preferably combined with each other.

### EXAMPLES

### Example 1

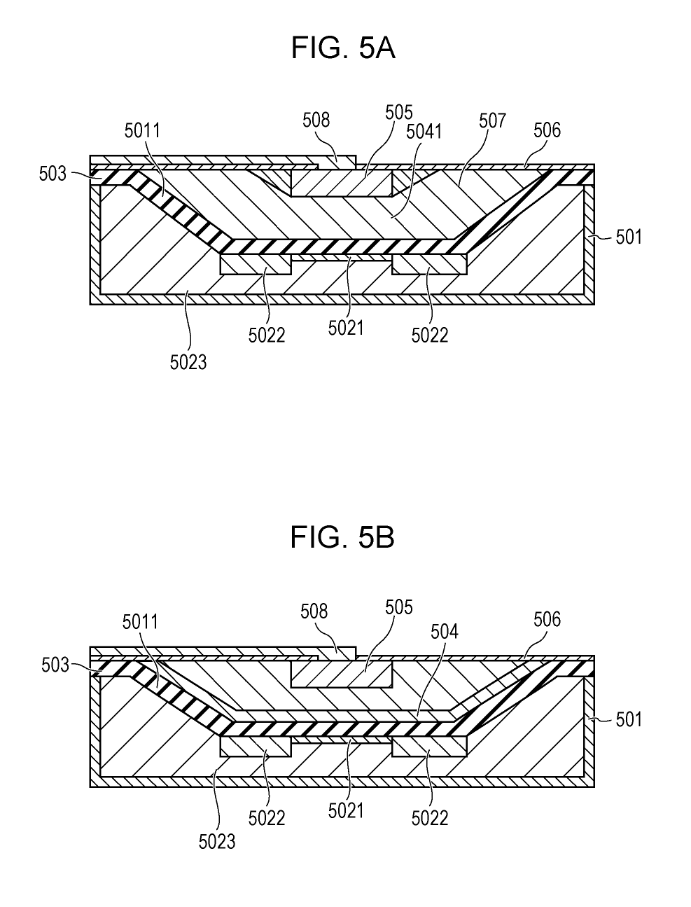

In this example, the preparation of a field-effect transistor sensor including a movable gate electrode is described with reference to FIGS. 5A and 5B.

An SiO₂ layer, which is not shown, is formed on a p-type (100) Si substrate 501 with a resistivity of 100 Ω·cm by thermal oxidation so as to have a thickness of 10 nm. A portion of the SiO₂ layer that corresponds to an opening of a trench 5011 is patterned by conventional lithography using a resist pattern.

The Si substrate 501 is immersed in buffered hydrofluoric acid prepared by mixing ammonium fluoride (NH₄F) and hydrofluoric acid (HF) at a ratio of 10:1 for three minutes, whereby the portion of the SiO₂ layer that corresponds to the opening is removed and the Si substrate 501 is partly exposed. After the resist pattern is removed, the Si substrate 501 is immersed in a 40% KOH solution for 30 seconds.

As a result, etching is stopped at a depth of 500 nm and the trench 5011 is formed under an opening of the SiO₂ layer so as to have a forward tapered shape.

The Si substrate 501 is immersed in buffered hydrofluoric acid prepared by mixing ammonium fluoride (NH₄F) and hydrofluoric acid (HF) at a ratio of 10:1 for three minutes, whereby the SiO₂ layer used as a mask is removed. The opening of the trench 5011 has an area of 100 μm².

SiO₂ is deposited to a thickness of 10 nm by low-pressure chemical vapor deposition (LPCVD).

A p-type well 5023 and a channel impurity layer 5021 are formed by conventional lithography and ion implantation. In particular, the p-type well 5023 is formed with an energy of 150 keV at a dose of 2.0×10¹³ cm⁻² using B ions and the channel impurity layer 5021 is formed with an energy of 20 keV at a dose of 2.0×10¹² cm⁻² using B ions.

Patterning is performed using a resist such that a region for forming a source/drain impurity layer 5022 below is open. P ions are implanted with an energy of 20 keV at a dose of 1.0×10¹³ cm⁻², whereby the source/drain impurity layer 5022 is formed.

SiN is deposited to a thickness of 50 nm by LPCVD, whereby an insulating layer 503 is formed.

The Si substrate 501 is immersed in a sulfuric acid-hydrogen peroxide mixture prepared by mixing H₂SO₄ and H₂O₂ at a ratio of 4:1 for five minutes, whereby the surface thereof is chemically oxidized.

Polysilicon is grown to a thickness of 300 nm by LPCVD, whereby a first sacrificial layer 5041 is formed.

A resist pattern having an opening is formed in a region for forming a gate electrode 505 by conventional lithography.

Fe is deposited to a thickness of 200 nm by ion beam-assisted vapor deposition. Thereafter, the resist pattern is removed and the gate electrode 505 is formed by a so-called lift-off method.

After the resist pattern is removed, Si is grown to a thickness of 500 μm by vapor deposition, whereby a second sacrificial layer 506 is formed.

The upper surface of the first sacrificial layer 5041 and the upper surface of the second sacrificial layer 506 are polished by a chemical mechanical polishing (CMP) method such that the insulating layer 503 and the gate electrode 505 are exposed. After slurry used for polishing is washed off, a plasma nitride layer with a thickness of 100 nm is formed and a gate-suspending portion 507 is formed.

A wiring line 508 is formed so as to be electrically connected to the gate electrode 505 through a contact hole.

These steps may be readily performed by conventional lithography and etching. After the gate-suspending portion 507 is patterned by lithography such that the trench 5011 is exposed and the gate-suspending portion 507 covers the gate electrode 505, the gate-suspending portion 507 is partly removed by reactive ion etching.

The first sacrificial layer 5041 and the second sacrificial layer 506 are removed by chemical dry etching. The use of chemical dry etching allows the first sacrificial layer 5041 and the second sacrificial layer 506 to be isotropically removed without damaging portions other than the first sacrificial layer 5041 and the second sacrificial layer 506. FIG. 5B is a sectional view after the first sacrificial layer 5041 and the second sacrificial layer 506 are removed.

The insulating layer 503 is kept in contact with a toluene solution of (2-bromo-2-methyl-N-6-(trimethoxysilyl)hexyl)propane amide for 12 hours.

Next, the insulating layer 503 is kept in contact with a DMF solution containing target molecules, methyl methacrylate, and pyridine in a nitrogen atmosphere and copper bromide is added to the DMF solution, followed by reaction for 24 hours.

The target molecules are washed off, whereby an adsorption site 504 may be formed on the insulating layer 503 and a sensor device is prepared.

The bonding strength between the adsorption site 504 and a target substance may be varied by replacing functional groups derived from methyl methacrylate with other functional groups.

### Example 2

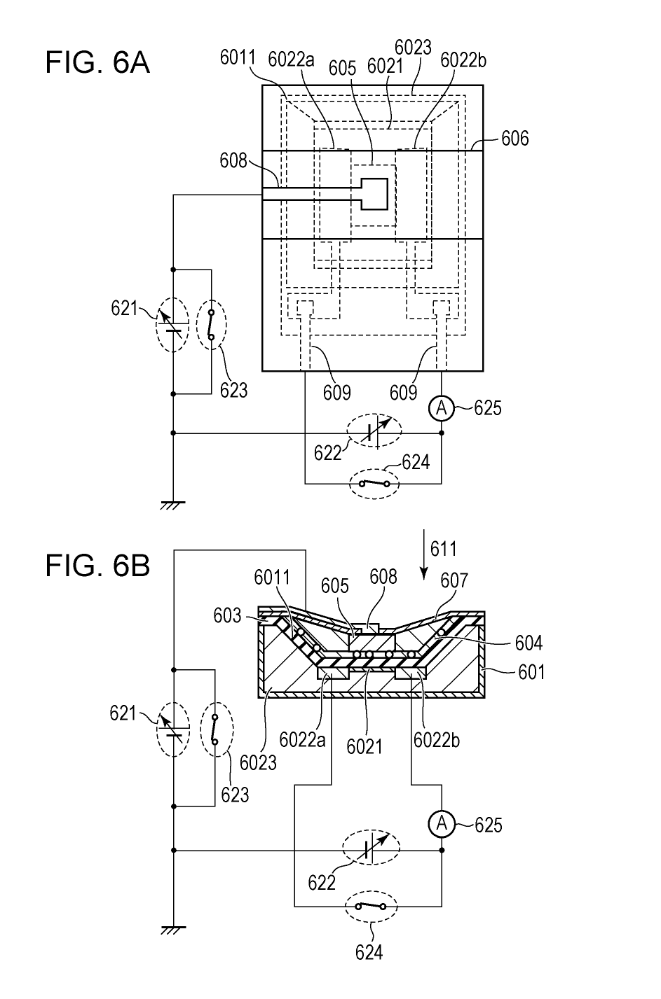

In this example, a method of detecting a target molecule using a field-effect transistor sensor including a movable gate electrode is described with reference to FIGS. 6A and 6B.

FIGS. 6A and 6B schematically show a sensor device and a circuit configuration for detection.

The sensor device shown in FIGS. 6A and 6B is prepared by the process described in Example 1 and an adsorption site 604 is formed from a polyvinyl phenol film.

Switches 623 and 624 are turned on, whereby a gate electrode 605, a source impurity layer 6022a, and a drain impurity layer 6022b are held at the same potential.

A voltage of +5 V is applied to a gate-source power supply 621 and a voltage of +1 V is applied to a source-drain power supply 622. In this example, voltage switches are used. When the gate-source power supply 621 and the source-drain power supply 622 are voltage-variable power supplies, voltages may be increased or decreased as required without using any switches.

In this state, gas containing ethanol 610, which is a target substance, is introduced into the sensor device and is adsorbed on the adsorption site 604. After a predetermined time is elapsed, a gradient magnetic field 611 is applied to the gate electrode 605, whereby the gate electrode 605 is moved close to the adsorption site 604 and a channel impurity layer 6021.

A gate-suspending portion 607 is 100 nm thick and has an opening with a length of 100 μm. Therefore, a deflection of about 300 nm is caused by applying a pressure of about 2 Pa to the gate-suspending portion 607.

The gate electrode 605 is made of Fe. Therefore, such a pressure may be readily generated by moving a known ferrite magnet close to the gate electrode 605.

The switches 623 and 624 are turned off, with the gradient magnetic field 611 applied to the gate electrode 605.

This allows voltages to be applied between a gate and a source and between the source and a drain such that the gate has a voltage of +5 V and the drain has a voltage of +1 V.

The current flowing through an ammeter 625 is monitored. A change in current due to the concentration of ethanol 610, which is a target substance, in the gas is obtained by comparison with the current measured in the absence of the gas.

While the disclosure has been described with reference to exemplary embodiments, it is to be understood that the embodiments is not limited to the disclosed exemplary embodiments. The scope of the following claims is to be accorded the broadest interpretation so as to encompass all such modifications and equivalent structures and functions.

This application claims the benefit of Japanese Patent Application No. 2011-110589 filed May 17, 2011, which is hereby incorporated by reference herein in its entirety.

What is claimed is:

1. A field-effect transistor comprising:
a semiconductor layer;
at least two active regions disposed in the semiconductor layer;
a source electrode in contact with one of the two active regions;
a drain electrode in contact with the other active region;
an insulating layer which is located between the source electrode and the drain electrode and which is disposed on the semiconductor layer;
a gate electrode overlying the insulating layer;
an adsorption site which is disposed between the gate electrode and the insulating layer and is used to adsorb a molecule; and
a driving unit used to drive the gate electrode.

2. The field-effect transistor according to claim 1, wherein the adsorption site is combined with the gate electrode or the insulating layer.

3. A sensing system comprising:
a voltage-applying unit;
a current-measuring unit; and
a sensing section,
wherein the sensing section includes the field-effect transistor according to claim 1.
